(19) United States
(12) Patent Application Publication
(10) Pub. No.: US 2026/0081512 A1
(43) Pub. Date: Mar. 19, 2026

(54) Control Circuitry for Zero Cross Detection In Ultra-Low Power DC-DC Converters

(71) Applicant: Green PMU Semi Private Limited, Telangana (IN)

(72) Inventor: Hafeez Koonari Thoombath, Kerala (IN)

(73) Assignee: Green PMU Semi Private Limited, Telangana (IN)

(21) Appl. No.: 19/185,228

(22) Filed: Apr. 21, 2025

(30) Foreign Application Priority Data
Sep. 18, 2024 (IN) 202441070551

(51) Int. Cl. H02M 1/00; G01R 19/04; G01R 19/175; H02M 3/158

(52) U.S. Cl. CPC H02M 1/0009; G01R 19/04; G01R 19/175; H02M 1/0032; H02M 3/158

(57) ABSTRACT

A control circuitry for zero cross detection of inductor current (I_{L}) is disclosed. The control circuitry includes an inductor, an nMOS low-side transistor switch and a pMOS high-side transistor switch. The control circuitry includes a peak detection circuit connected to the pMOS high-side transistor switch and configured to detect peaking of a drain voltage (VD) of the high-side transistor switch and generate a clock signal (CLK) if the drain voltage (VD) peaking is detected in an inductor current cycle. The control circuitry includes a D flip-flop connected to the peak detection circuit and operable based on the clock signal (CLK) generated by the peak detection circuit. The control circuitry includes a zero cross detector circuit coupled to the D flip-flop and the high-side transistor switch to detect zero crossing of the inductor current.

### CROSS REFERENCE TO RELATED APPLICATIONS

The present disclosure takes priority from the Indian patent application 202441070551,filed on Sep. 18, 2024, and the entire contents of the priority patent application are incorporated herein by reference.

### FIELD OF THE INVENTION

The present disclosure relates to zero cross detection in DC to DC converters, and in particular, to zero cross detection in ultra-low power DC-DC converters.

### BACKGROUND TO THE INVENTION

Direct Current (DC) to DC converters, for example, buck converters, boost converters, and buck-boost converters, convert a direct current from one voltage level to another. DC-DC converters generally function in either of two modes, i.e., continuous conduction mode (CCM) or discontinuous conduction mode (DCM). The key difference between CCM and DCM is that, in CCM, the inductor current can exhibit negative flow in low power applications. In DCM, measures are taken to prohibit negative inductor current flow. Typically, in ultra-low power applications, a DC-DC converter functioning in DCM is preferred.

Existing circuit configuration of a boost (DC-DC) converter (100) functioning in DCM mode includes an n-type metal oxide semiconductor (nMOS) transistor switch (M1) and a p-type metal oxide semiconductor (pMOS) transistor switch (M2) connected to an inductor (L), as illustrated in FIG. 1A. The nMOS switch is considered as the low-side switch (M1) and the pMOS switch is considered as the high-side switch (M2). The boost converter (100) includes a zero current detector (ZCD) configured to deactivate the pMOS transistor switch (M2) (the high-side switch) when the inductor current (I_{L}) reaches zero. The control block determines the pulse width, and a clock circuit provides clocking signals. The nMOS clock signal (CLKN) and the pMOS clock signal (CLKP) are provided to the nMOS switch and the pMOS switch, respectively. The CLKN and the CLKP are illustrated in FIG. 1B.

In the first half cycle of clocking, when the low-side switch M1 is ON and the high-side switch M2 is OFF, the drain voltage (VD) is zero. The inductor (L) is charged and the inductor current (I_{L}) passes through low-side switch M1 to ground. In the second half cycle when the low-side switch M1 is OFF and the high-side switch M2 is ON, the inductor (L) discharges through the high-side switch M2. In this instance, ideally the inductor current (I_{L}) should be zero. However, the inductor current (I_{L}) may become negative. When the inductor current (I_{L}) becomes negative, the boost (DC-DC) converter (100) will draw current from output (Vo) reducing the efficiency of the boost (DC-DC) converter (100). The inductor current characteristics during an early activation of the high-side switch M2 or a delayed (late) deactivation of the high-side switch M2 is illustrated in FIG. 1B. It is important that during DCM operation, the high-side switch (M2) is deactivated exactly when the inductor current (I_{L}) is zero (zero crossing detection) and before negative current flow occurs.

There exists several circuit configurations for zero crossing detection. In one existing circuit configuration, a comparator (205) is used to detect zero crossing as illustrated in FIG. 2. However, in order for the circuit to detect zero crossing accurately, the comparator (205) has to be operating at high speed, which will draw high current from the circuit. Further, the comparator (205) will have an offset, causing inaccurate detection.

In another existing circuit configuration, the drain voltage (VD) is provided as data (D) input to a D flip-flop (330). The D flip-flop (330) captures the value of the drain voltage (VD) based on the clock input CLKP as illustrated in FIG. 3 (a). It is to be noted that the clock input CLKP is the same signal that deactivates the high-side transistor switch (M2) but is given with a delay as input (CLK) to the D flip-flop (330). When the high-side transistor switch (M2) is prematurely (early) deactivated or turned OFF early (prior to the inductor current reaching zero), it continues to conduct with a considerably higher voltage drop. Consequently, the node VD remains at an elevated level even after the high-side transistor (M2) is switched OFF. This elevated voltage persists until the inductor current (I_{L}) eventually reaches zero. Conversely, if the high-side transistor (M2) has a delayed (late) deactivation or turned OFF, the voltage rapidly drops to zero immediately after the high-side transistor (M2) deactivation. By sampling the high/low state of the drain voltage (VD) shortly after the high-side transistor (M2) is deactivated, it can be determined whether the high-side transistor (M2) was turned OFF before or after the inductor current (I_{L}) dropped to zero. The output of D flip-flop (330) provides information about whether the zero crossing occurred early or with a delay. This sensed and quantized signal is sent to a control circuit that selects a pulse width that sets the state of the high-side transistor (M2) for switching near the zero-current crossing. The inductor peak current or high-side transistor (M2) switching time can be adjusted based on the ZCD information acquired by sampling the VD node with the CLK signal using the D flip-flop (330). For instance, if the ZCD is delayed, the system increases the inductor peak current or reduces the high-side transistor (M2) switching time in the upcoming cycles, and vice versa. This is generally implemented with the help of up/down counter.

Sampling the VD node using the CLK signal presents its own set of challenges. Firstly, to determine whether the zero crossing occurred early or late is based on the delay of the CLK signal (Δt), as depicted in FIG. 3 (b). In situations where the CLK signal delay is minimal, there is a risk of consistently sampling VD as being in a HIGH state. Further, in situations where the CLK signal experiences some delay, the flip-flop will sample either the zero voltage or the oscillation of the VD node as shown in FIG. 3(b). If this inaccurate data is utilized by the feedback system to adjust the inductor peak current or high-side transistor (M2) switching time, the overall system efficiency will further decrease.

Therefore, there is a need for a circuit and method to accurately determine zero crossing of the inductor current and to switch OFF the high-side transistor (M2).

### SUMMARY OF THE INVENTION

This summary is provided to introduce a selection of concepts in a simple manner that is further described in the detailed description of the disclosure. This summary is not intended to identify key or essential inventive concepts of the subject matter nor is it intended for determining the scope of the disclosure.

An objective of the present disclosure is to provide a circuitry for inductor peak current control in a DC-DC converter.

Another objective of the present disclosure is to provide a circuitry for accurately detecting inductor current crossing zero in the DC-DC converter.

Accordingly, in accordance with an embodiment of the present disclosure, a control circuitry for zero cross detection of inductor current (I_{L}) is disclosed. The control circuitry includes an inductor comprising a first end and a second end. The control circuitry includes a low-side transistor switch and a high-side transistor switch. The low-side transistor switch and the high-side transistor switch are connected to the second end of the inductor and operable to provide one of a charging path and a discharging path for the inductor current (I_{L}). The control circuitry includes a peak detection circuit connected to the high-side transistor switch and configured to detect peaking of a drain voltage (VD) of the high-side transistor switch and generate a clock signal (CLK), if the drain voltage (VD) peaking is detected in an inductor current cycle, wherein a presence of the clock signal (CLK) is indicative of an early switching OFF of the high-side transistor switch, thereby indicative of an early zero crossing of the inductor current (I_{L}), wherein an absence of the clock signal (CLK) in the inductor current cycle is indicative of a delayed switching OFF of the high-side transistor switch, thereby indicative of a delayed zero crossing of the inductor current (I_{L}). The control circuitry includes a D flip-flop connected to the peak detection circuit and operable based on the clock signal (CLK) generated by the peak detection circuit. The D flip-flop is configured to generate a digital HIGH output signal if the clock signal (CLK) is present and generate a digital LOW output signal if the clock signal (CLK) is absent. The control circuitry includes a zero cross detector circuit coupled to the D flip-flop and the high-side transistor switch to detect zero crossing of the inductor current.

Accordingly, in accordance with an embodiment of the present disclosure a method for zero cross detection of inductor current (I_{L}) is disclosed. The method includes detecting, by a peak detection circuit, peaking of a drain voltage (VD) of a high-side transistor switch. The method includes generating, by the peak detection circuit, a clock signal (CLK), if the drain voltage (VD) peaking is detected in an inductor current cycle, wherein a presence of the clock signal (CLK) is indicative of an early switching OFF of the high-side transistor switch, thereby indicative of an early zero crossing of the inductor current (I_{L}), wherein an absence of the clock signal (CLK) in the inductor current cycle is indicative of a delayed switching OFF of the high-side transistor switch, thereby indicative of a delayed zero crossing of the inductor current (I_{L}). The method includes generating, by a D flip-flop, a digital HIGH output signal if the clock signal (CLK) is present and generating, by the D flip-flop, a digital LOW output signal if the clock signal (CLK) is absent.

To further clarify advantages and features of the present invention, a more particular description of the invention will be rendered by reference to specific embodiments thereof, which is illustrated in the appended figures. It is to be appreciated that these figures depict only typical embodiments of the invention and are therefore not to be considered limiting of its scope. The invention will be described and explained with additional specificity and detail with the accompanying figures.

### BRIEF DESCRIPTION OF THE FIGURES

The invention will be described and explained with additional specificity and detail with the accompanying figures in which:

FIG. 1A illustrates a schematic diagram of a boost converter, in accordance with a prior art;

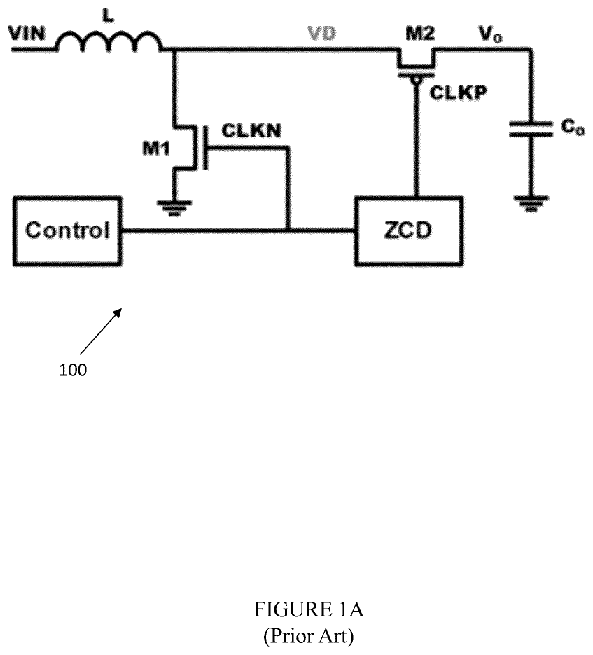

FIG. 1B illustrates a timing diagram of the inductor current response to clock signals in the boost converter, in accordance with a prior art;

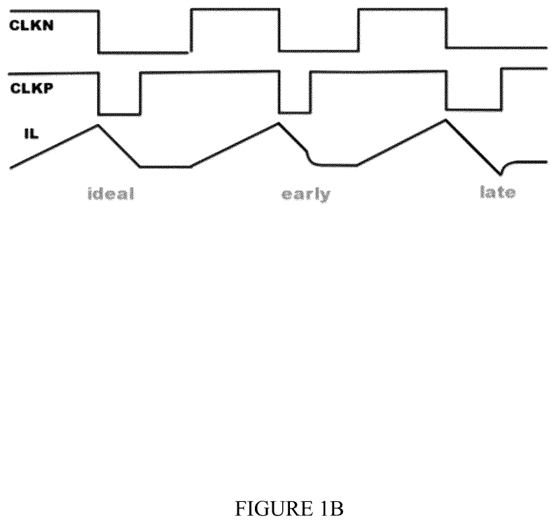

FIG. 2 illustrates a schematic diagram of a zero crossing detector with a comparator, in accordance with a prior art;

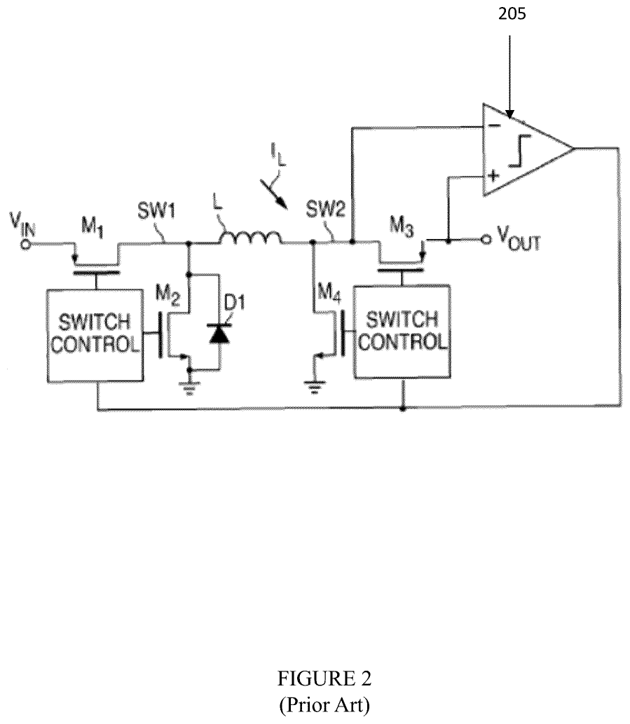

FIG. 3 (a) illustrates a schematic diagram of a zero crossing detector with a D flip-flop, in accordance with a prior art;

FIG. 3 (b) is a diagrammatic representation of clock signals of the D flip-flop, in accordance with a prior art;

FIG. 4A illustrates a schematic diagram of a control circuitry for zero cross detection and peak detection, in accordance with an embodiment of the present disclosure;

FIG. 4B illustrates a timing diagram of the inductor current response to clock signals, in accordance with an embodiment of the present disclosure;

FIG. 4C (a) and (b) is a diagrammatic representation comparing clock signals of the D flip of a prior art with the clock signals of the D flip in the present disclosure;

FIG. 5 illustrates a schematic diagram of a control circuitry for zero cross detection comprising a peak detector implemented using a comparator, in accordance with an embodiment of the present disclosure;

FIG. 6 illustrates a schematic diagram of a control circuitry for zero cross detection comprising a peak detector implemented using a high value resistor, in accordance with an embodiment of the present disclosure;

FIG. 7A illustrates a schematic diagram of a control circuitry for zero cross detection comprising a peak detector implemented using a current source, in accordance with an embodiment of the present disclosure;

FIG. 7B illustrates a timing diagram of the inductor current response to clock signals, in accordance with an embodiment of the present disclosure; and FIG. 8 illustrates a method for zero cross detection of inductor current, in accordance with an embodiment of the present disclosure.

Further, skilled artisans will appreciate that elements in the figures are illustrated for simplicity and may not have been necessarily drawn to scale. Furthermore, in terms of the construction of the system, one or more components of the system may have been represented in the figures by conventional symbols, and the figures may show only those specific details that are pertinent to understanding the embodiments of the present invention so as not to obscure the figures with details that will be readily apparent to those of ordinary skill in the art having benefit of the description herein.

### DESCRIPTION OF THE INVENTION

For the purpose of promoting an understanding of the principles of the invention, reference will now be made to the embodiment illustrated in the figures and specific language will be used to describe the same. It will nevertheless be understood that no limitation of the scope of the invention is thereby intended, such alterations and further modifications in the illustrated system, and such further applications of the principles of the invention as illustrated therein being contemplated as would normally occur to one skilled in the art to which the invention relates.

It will be understood by those skilled in the art that the foregoing general description and the following detailed description are exemplary and explanatory of the invention and are not intended to be restrictive thereof.

In the present disclosure, relational terms such as first and second, and the like, may be used to distinguish one entity from the other, without necessarily implying any actual relationship or order between such entities.

The terms “comprises”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components proceeded by “comprises . . . a” does not, without more constraints, preclude the existence of other devices or other sub-systems or other elements or other structures or other components or additional devices or additional sub-systems or additional elements or additional structures or additional components. Appearances of the phrase “in an embodiment,” “in another embodiment” and similar language throughout this specification may, but do not necessarily, all refer to the same embodiment.

Unless otherwise defined, all technical and scientific terms used herein have the same meaning as commonly understood by one of ordinary skill in the art to which this invention belongs. The system, methods, and examples provided herein are illustrative only and not intended to be limiting.

Embodiments of the present disclosure relates to zero crossing detection in a DC-DC converter. A boost converter in DCM mode is considered herewith.

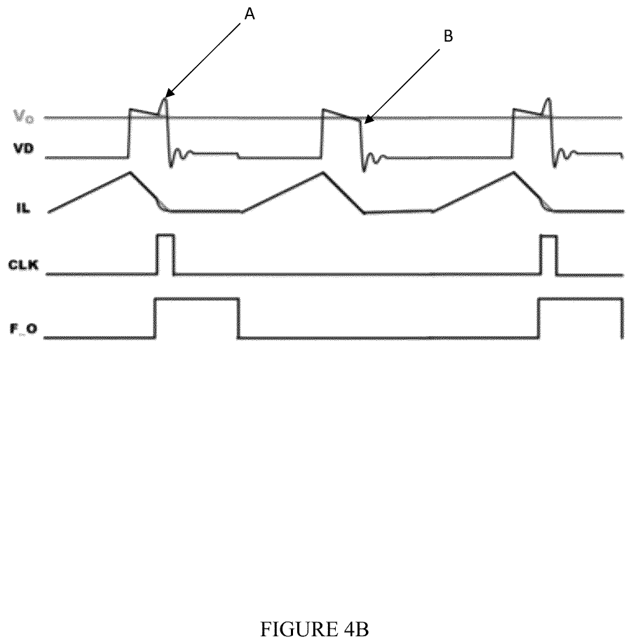

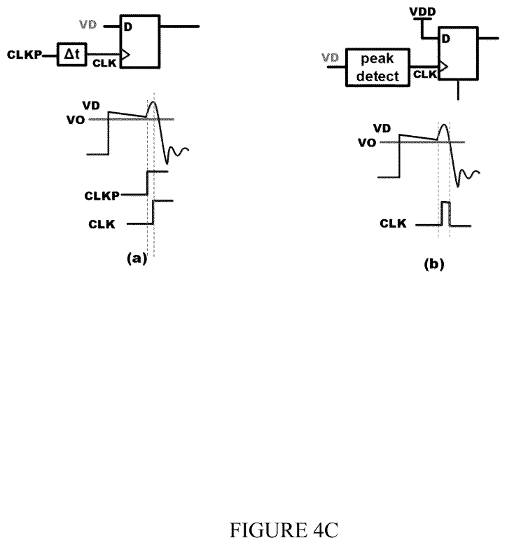

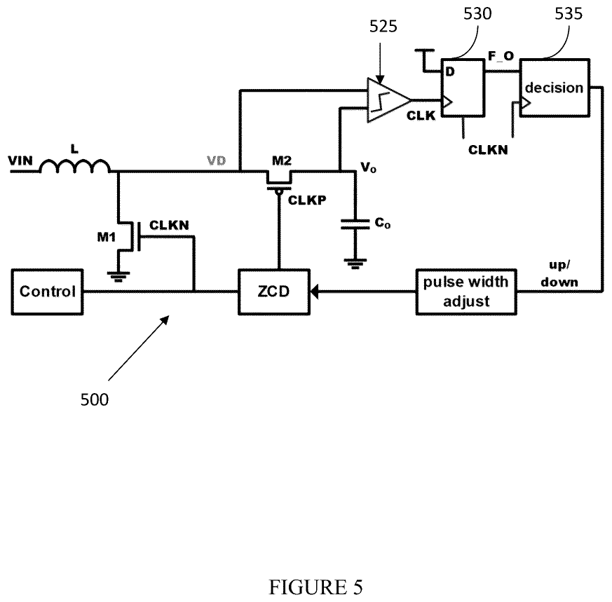

FIG. 4A illustrates a schematic diagram of a control circuitry (400) for zero cross detection and peak detection, in accordance with an embodiment of the present disclosure. The control circuitry (400) is a boost type DC-DC converter for ultra-low power applications. Ultra-low-power DC-DC converters find application in various power management systems, including micro-scale energy harvesting, portable devices, wearables, and medical implants. These converters are essential components, necessitating exceptionally low quiescent power consumption to effectively operate within scenarios characterized by low power demands. The Zero Cross Detector (ZCD) constitutes a crucial component within DC-DC converters, functioning in the discontinuous conduction mode (DCM). DC-DC converters with low power usage predominantly operate in the DCM, where the efficiency of the system significantly hinges on the power consumption and precision of the ZCD.

The functioning of a DC-DC converter depends on the speed at which the ZCD operates. However, higher operational speed requires higher power dissipation. Embodiments of the present disclosure include an ZCD having ultra-low power dissipation, no static power dissipation, and nano-amps of current consumption.

Referring to FIG. 4A, the control circuitry (400) for zero cross detection of inductor current (I_{L}) includes an inductor (L) (405). The inductor (405) can be a coil having a first end (405a) and a second end (405b). The control circuitry (400) includes an nMOS low-side transistor switch (410) (M1) and a pMOS high-side transistor switch (415) (M2). The nMOS low-side transistor switch (410) (M1) and the pMOS high-side transistor switch (415) (M2) are connected to the second end (405b) of the inductor (405) and operable to provide one of a charging path and a discharging path for the inductor current (I_{L}).

The control circuitry (400) can be considered to have two sub circuits, a first sub circuit for inductor peak current control and a second sub circuit for detecting inductor current zero crossing. The inductor peak current control is achieved by a peak detection circuit (425).

The peak detection circuit (425) is connected to the high-side transistor switch (415). The peak detection circuit (425) is configured to detect peaking of a drain voltage (VD) of the high-side transistor switch (415). In the first half cycle, when M1 is ON and M2 is OFF, the drain voltage (VD) is zero. The inductor (L) is charged and the inductor current (I_{L}) passes through M1 to ground. In the second half cycle when M1 is OFF and M2 is ON, the inductor (L) discharges through M2, and ideally the inductor current (I_{L}) should be zero. However, the inductor current (I_{L}) may become negative. When the inductor current (I_{L}) becomes negative, the control circuitry (400) will draw current from output (Vo) reducing the efficiency of the control circuitry (400). If the M2 switch is closed before it reaches zero, the remaining current has to flow through the body diode of the MOSFET and this will create a small overshoot (A) in the voltage (VD) and if the M2 switch is closed after the zero crossing, a dip (B) in the volage (VD) is observed as illustrated in FIG. 4B.

The peak detection circuit (425) is configured to generate a clock signal (CLK) if the drain voltage (VD) peaking is detected in an inductor current cycle. It is to be noted that a presence of the clock signal (CLK) is indicative of an early switching OFF of the high-side transistor switch (415), thereby indicative of an early zero crossing of the inductor current (IL). Also, an absence of the clock signal (CLK) in the inductor current cycle is indicative of a delayed switching OFF of the high-side transistor switch (415), thereby indicative of a delayed zero crossing of the inductor current (IL).

The control circuitry (400) includes a Data (D) flip-flop (430) connected to the peak detection circuit (425). The D flip-flop (430) is operable based on the clock signal (CLK) generated by the peak detection circuit (425). The D flip-flop (430) is operable to generate a digital output, F_O. The D flip-flop (430) is configured to generate a digital HIGH output signal if the clock signal (CLK) is present. The D flip-flop (430) is configured to generate a digital LOW output signal (or no signal) if the clock signal (CLK) is absent.

The control circuitry (400) includes a zero cross detector circuit (ZCD) (435) coupled to the D flip-flop (430) and the high-side transistor switch (415) M2 to detect zero crossing of the inductor current. The ZCD (435) monitors the inductor current and turns the high-side transistor switch (415) M2 OFF when it crosses zero, preventing further current flow. It is to be noted that the CLK signal determines the zero-crossing time for subsequent cycles. It indicates whether the high-side transistor switch (415) is closing early or late. For instance, during the inductor cycle, if there is an overshoot (early closing), the CLK signal is generated. Conversely, if the clock is not generated within one inductor cycle, it signals late switch closure, as illustrated in FIG. 4B. In steady state, the zero-current crossing of the inductor oscillates around zero, and the clock is generated every other cycle.

The control circuitry (400) is configured to adjust the inductor peak current based on the clock signal (CLK). In one embodiment, the control circuitry may adjust switching time of the high-side transistor switch (415) based on the clock signal (CLK). The control circuitry (400) includes an up/down counter (440) connected to the D flip-flop (430) to adjust pulse width and thereby switching time of the high-side transistor switch (415). The control circuitry (400) includes a control module (445) to determine pulse width of the output voltage (Vo) or the input voltage (Vin). The control module (445) selects a pulse width that sets the state of the high-side transistor switch (M2) for switching near the zero-current crossing.

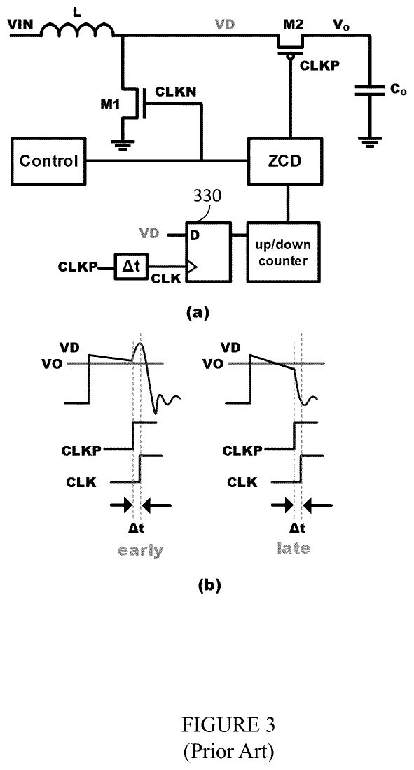

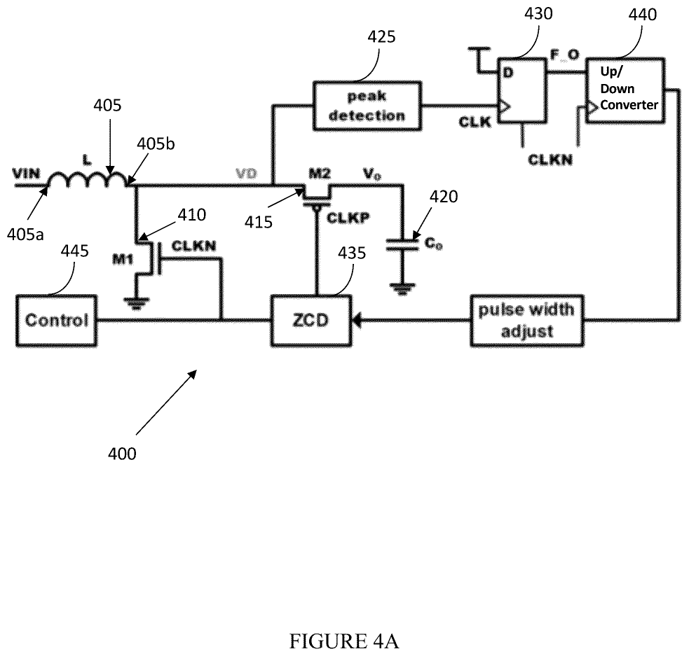

Referring to FIG. 4C (a) and FIG. 4C (b), FIG. 4C (a) is a diagrammatic representation of the clock signals of the D flip of the prior art disclosed in FIG. 3 (a) (b) and FIG. 4C (b) represents the clock signals of the D flip in the present disclosure. In the prior art, in FIG. 3 (a) (b), the D flip-flop (330) captures the value of the drain voltage (VD) based on the clock input CLKP. It is to be noted that the clock input CLKP is the same signal that deactivates the high-side transistor switch (M2) but is given with a delay as input (CLK) to the D flip-flop (330). The prior art has limitations, in situations where the CLK signal delay is minimal, there is a risk of consistently sampling VD as being in a HIGH state and if the CLK signal experiences some delay, the flip-flop will sample either the zero voltage or the oscillation of the VD node.

In contrast, in the present disclosure, in FIG. 4A, the D flip-flop (430) is operable based on the clock signal (CLK) generated by the peak detection circuit (425). The peak detection circuit (425) detects VD overshoot and generates a clock signal (CLK) in FIG. 4A. Further, the D flip-flop (430) is configured to generate a digital HIGH output signal if the clock signal (CLK) is present and to generate a digital LOW output signal (or no signal) if the clock signal (CLK) is absent. The clock signal (CLK) in the present disclosure provides information of the zero crossing based on the voltage peaking. This method of detecting zero crossing is accurate if there is a delayed or early switching OFF of the high-side transistor switch (415).

There are various embodiments of the present disclosure and of the control circuitry (400) based on how the peak detection circuit (425) is operated.

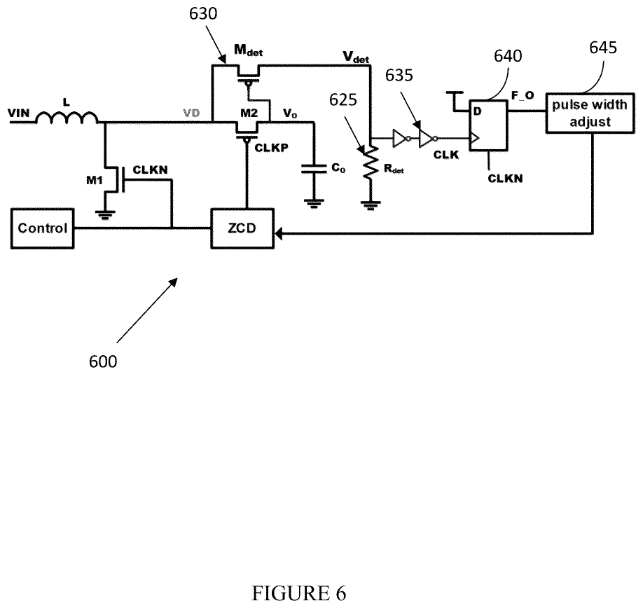

In one embodiment, the peak detection circuit includes a comparator (525) as illustrated in FIG. 5. This comparator (525) can be of low power and slow because the information is used only in the upcoming inductor cycle, unlike the comparator (205) disclosed in prior art 2 which needs to be for speed and delay. The comparator (525) output is given as a clock signal (CLK) to a D flip-flop (530). The control circuitry (500) is configured to adjust the inductor peak current or switching time of the high-side transistor switch M2 based on the clock signal (CLK). This decision whether to adjust the inductor peak current or switching time of the high-side transistor switch M2 is performed using a decision block (535). The control circuitry (400) includes an up/down counter connected to the D flip-flop (530) to adjust pulse width and to adjust the switching time of the high-side transistor switch M2.

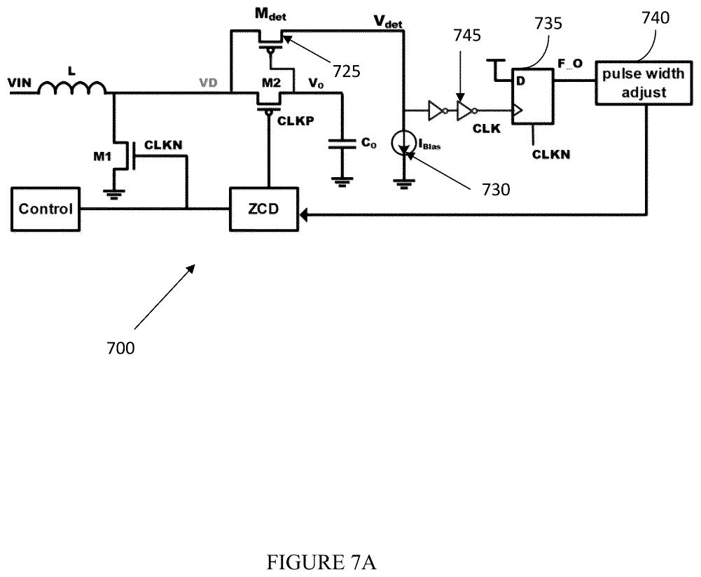

In one embodiment, the peak detection circuit includes a high value resistor (625) as illustrated in FIG. 6. In this control circuitry (600) in FIG. 6, if the high-side transistor switch M2 is closed before it reaches zero, the peaking of VD happens and part of the inductor current flows to the resistor through MOSFET (630) Mdet. This inductor current that is flowing through the MOSFET (630) will develop a voltage across the resistor (625) Rdet. The resistor value has to be very high such that the voltage developed across the resistor (625) should be enough to trip an inverter or Schmitt trigger. The Schmitt trigger consisting of two inverters (two NOT gates) can increase the drive strength, sharpen edges of the input signal from the resistor (625), and isolate impact of load. In FIG. 6, the voltage developed across the resistor (625) trips a Schmitt trigger (635). The Schmitt trigger (635) provides the clock signal (CLK) input to the D flip-flop (640), wherein the D flip-flop (640) is configured to output a signal (F_O). Further, the control circuitry (600) is configured to adjust pulse width (645) and adjust switching time of the high-side transistor switch M2 based on the clock signal (CLK).

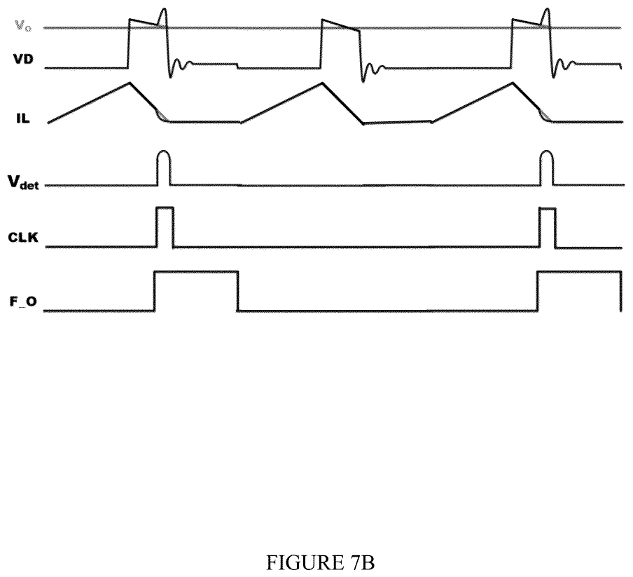

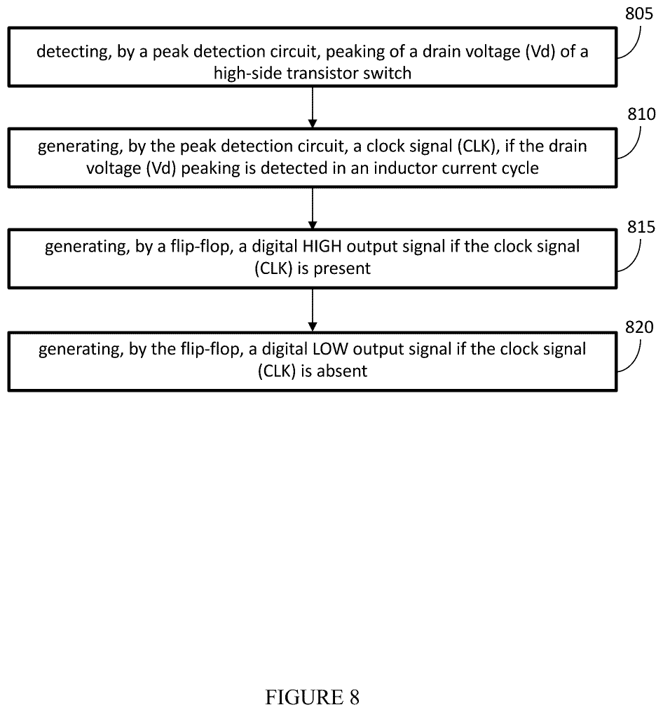

In one embodiment, the peak detection circuit includes a current source (730) as illustrated in FIG. 7A. One of the most preferred embodiments is the control circuitry (700). The current source (730) can be in the range of few nano amperes (nA). In this control circuitry in FIG. 7A, if the high-side transistor switch M2 is closed before it reaches zero, the peaking of VD happens and part of the inductor current flows to the resistor through MOSFET (725) Mdet. If there is no peaking of the VD, the node voltage Vdet will be zero and no current flows through the current source (730). If VD peaking happens, current in the range of milli amps/micro amps flow to the net Vdet and it cannot be absorbed by the current source (730). Therefore, the voltage at node Vdet shoots up and triggers the inverter/Schmitt trigger (745) to generate the clock signal (CLK), indicating an early closing of the high-side transistor switch M2. Further, the control circuitry (700) is configured to adjust pulse width (740) and adjust switching time of the high-side transistor switch M2 based on the clock signal (CLK). FIG. 7B illustrates a timing diagram of the inductor current response based on VD, the Vdet response, the output of the Schmitt trigger (745), i.e., the clock signal CLK and the output of the D flip-flop (735), i.e., output F_O.

The control circuitry (400), (500), (600), and (700) includes a clocking circuit to generate a clocking signal (CLKN) for the switching ON and switching OFF of the low-side transistor switch M1 and a clocking signal (CLKP) for the switching ON and switching OFF of the high-side transistor switch M2. It is to be noted that the D flip-flop and the up/down counter are clocked using the clocking signal CLKN and it is to be noted that this CLKN signal clocking the D flip-flop is different from the CLK input signal to the D flip-flop.

FIG. 8 illustrates a method for zero cross detection of inductor current, in accordance with an embodiment of the present disclosure

Step 805 represents a method whereby a peak detection circuit detects peaking of the drain voltage (VD) of a high-side transistor switch (415) M2. The peaking of the VD can be determined using a comparator or a high value resistor or a current source.

At step 810, the method includes generating, by the peak detection circuit (425), a clock signal (CLK), if the drain voltage (VD) peaking is detected in an inductor current cycle. It is to be noted that a presence of the clock signal (CLK) is indicative of an early switching OFF of the high-side transistor switch (415), thereby indicative of an early zero crossing of the inductor current (I_{L}), and an absence of the clock signal (CLK) in the inductor current cycle is indicative of a delayed switching OFF of the high-side transistor switch (415), thereby indicative of a delayed zero crossing of the inductor current (I_{L}).

At step 815, the method includes generating, by a flip-flop (430), a digital HIGH output signal if the clock signal (CLK) is present. The D flip-flop (430) is operable based on the clock signal (CLK) generated by the peak detection circuit (425).

At step 820, the method includes generating, by the flip-flop (430), a digital LOW output signal (or no signal) if the clock signal (CLK) is absent.

The method includes detecting zero crossing of the inductor current based on the clock signal (CLK). The ZCD (435) monitors the inductor current and turns the high-side transistor switch (415) M2 OFF when it crosses zero.

There are various advantages of the control circuitry (400) and the ZCD (435). The control circuitry (400) and the ZCD (435) provides ultra-low power dissipation, no static power dissipation, and nano-amps of current consumption. The clock signal (CLK) in the present disclosure provides information of the zero crossing based on the voltage peaking. This method of detecting zero crossing using the control circuitry (400) and the ZCD (435) is accurate if there is a delayed or early switching OFF of the high-side transistor switch M2.

While specific language has been used to describe the disclosure, any limitations arising on account of the same are not intended. As would be apparent to a person skilled in the art, various working modifications may be made to the method in order to implement the inventive concept as taught herein.

The figures and the foregoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

What is claimed is:

1. A control circuitry for zero cross detection of inductor current (I_{L}), the control circuitry comprising:
an inductor comprising a first end and a second end;
an n-type metal oxide semiconductor (nMOS) low-side transistor switch and a p-type metal oxide semiconductor (pMOS) high-side transistor switch, wherein the nMOS low-side transistor switch and the pMOS high-side transistor switch are connected to the second end of the inductor and operable to provide one of a charging path and a discharging path for the inductor current (I_{L});
a peak detection circuit connected to the pMOS high-side transistor switch and configured to:
detect peaking of a drain voltage (VD) of the pMOS high-side transistor switch; and
generate a clock signal (CLK), if the drain voltage (VD) peaking is detected in an inductor current cycle,
wherein a presence of the clock signal (CLK) is indicative of an early switching OFF of the pMOS high-side transistor switch, thereby indicative of an early zero crossing of the inductor current (I_{L}),
wherein an absence of the clock signal (CLK) in the inductor current cycle is indicative of a delayed switching OFF of the pMOS high-side transistor switch, thereby indicative of a delayed zero crossing of the inductor current (I_{L});
a D flip-flop connected to the peak detection circuit and operable based on the clock signal (CLK) generated by the peak detection circuit, wherein the D flip-flop is configured to:
generate a digital HIGH output signal if the clock signal (CLK) is present;
generate a digital LOW output signal if the clock signal (CLK) is absent; and
a zero cross detector circuit coupled to the D flip-flop and the pMOS high-side transistor switch to detect zero crossing of the inductor current (I_{L}).

2. The control circuitry as claimed in claim 1, wherein the peak detection circuit comprises a comparator.

3. The control circuitry as claimed in claim 1, wherein the peak detection circuit comprises a high value resistor.

4. The control circuitry as claimed in claim 1, wherein the peak detection circuit comprises a current source.

5. The control circuitry as claimed in claim 1, wherein the control circuitry is configured to perform one of:
adjusting the inductor peak current based on the clock signal (CLK);
adjusting switching time of the pMOS high-side transistor switch based on the clock signal (CLK).

6. The control circuitry as claimed in claim 5, comprising an up/down counter connected to the D flip-flop to adjust the switching time of the pMOS high-side transistor switch.

7. The control circuitry as claimed in claim 1, comprising a clocking circuit to generate clocking signals for the switching ON and switching OFF of the nMOS low-side transistor switch and the pMOS high-side transistor switch, respectively.

8. The control circuitry as claimed in claim 1, comprising a control module to determine pulse width of the output voltage (Vo) or the input voltage (Vin).

9. A method for zero cross detection of inductor current (I_{L}), the method comprising:
detecting, by a peak detection circuit, peaking of a drain voltage (VD) of a pMOS high-side transistor switch;
generating, by the peak detection circuit, a clock signal (CLK), if the drain voltage (VD) peaking is detected in an inductor current cycle,
wherein a presence of the clock signal (CLK) is indicative of an early switching OFF of the high-side transistor switch, thereby indicative of an early zero crossing of the inductor current (I_{L}),
wherein an absence of the clock signal (CLK) in the inductor current cycle is indicative of a delayed switching OFF of the high-side transistor switch, thereby indicative of a delayed zero crossing of the inductor current (I_{L});
generating, by a D flip-flop, one of:
a digital HIGH output signal if the clock signal (CLK) is present; and
a digital LOW output signal if the clock signal (CLK) is absent.

10. The method as claimed in claim 9, comprising, detecting, by a ZCD, zero crossing of the inductor current based on the clock signal (CLK).
